(19) United States
(12) Patent Application Publication
(10) Pub. No.: US 2025/0311255 A1
(43) Pub. Date: Oct. 2, 2025

(54) HIGH DENSITY MIM CAPACITOR RESILIENT TO HIGH TEMPERATURE, HIGH PRESSURE, AND LONG DURATION HYDROGEN OR DEUTERIUM ANNEAL

(71) Applicant: Intel Corporation, Santa Clara, CA (US)

(72) Inventors: Cheyun Lin, Milwaukie, OR (US); Dragos Seghete, Portland, OR (US); Ibrahim Azad, North Plains, OR (US); Tian-Wei Goh, Hillsboro, OR (US); Rachel Thorman, Beaverton, OR (US)

(73) Assignee: Intel Corporation, Santa Clara, CA (US)

(21) Appl. No.: 18/621,644

(22) Filed: Mar. 29, 2024

(51) Int. Cl. H01L 21/02; H01L 27/06

(52) U.S. Cl. CPC H10D 1/714; H01L 21/02178; H01L 21/02181; H01L 21/0228; H01L 21/02507; H10D 84/811

(57) ABSTRACT

Apparatuses, systems, and techniques related to material systems for metal-insulator-metal (MIM) capacitors over a device layer including field effect transistors are described. The insulator of the MIM capacitor is a superlattice of interleaved first and second materials. The first material is hafnium or zirconium oxide, and the second material includes aluminum such that the superlattice has a relatively low aluminum concentration. The MIM capacitor is over a device layer including a transistor having a gate dielectric including an oxide material.

### BACKGROUND

Higher performance, lower cost, increased miniaturization, and greater density of integrated circuits are ongoing goals of the electronics industry. In some integrated circuit devices, transistors such as fin field-effect transistors (FinFETs) and metal-insulator-metal (MIM) capacitors such as deep hole or deep trench capacitors are integrated on the same integrated circuit die. In some contexts, a high temperature, high pressure, and long duration hydrogen and/or deuterium anneal is a processing operation in the fabrication of the transistor and MIM capacitor integrated circuit device. For example, the hydrogen and/or deuterium anneal may passivate dangling bonds in the transistor gate oxide by diffusing hydrogen and/or deuterium through the interconnect stack, which includes the MIM capacitors. Such processing can cause degradation of the insulator material of the MIM capacitors.

It is with respect to these and other considerations that the present improvements are needed. Such improvements may become critical as the desire to deploy advanced integrated circuit devices becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a schematic of an example capacitor;

FIG. 2 illustrates a cross-sectional side view of an example multi-layer material stack for use in a capacitor;

FIG. 3 illustrates a cross-sectional side view of an example capacitor device structure having an anneal resilient insulator layer;

FIG. 4 illustrates a cross-sectional side view of an exemplary deep trench capacitor 400 having an anneal resilient insulator layer;

FIG. 5 illustrates a cross-sectional side view of an integrated circuit (IC) device structure including transistor structures in a device layer, and a metal-insulator-metal (MIM) capacitor within metallization layers over the device layer;

FIG. 6 is a flow diagram illustrating methods for forming a capacitor device structure having an anneal resilient insulator layer and annealing an underlying field effect transistor;

FIGS. 7A, 7B, 7C, 7D, 7E, 7F, and 7G are cross-sectional views of a device structure evolving as the methods of FIG. 6 are practiced;

FIG. 8 illustrates exemplary systems employing an IC die having a capacitor device structure with an anneal resilient insulator layer and an underlying field effect transistor; and

FIG. 9 is a functional block diagram of an electronic computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. Herein, the term “predominantly” indicates not less than 50% of a particular material or component while the term “substantially pure” indicates not less than 95% of the particular material or component and the term “pure” indicates not less than 99% of the particular material or component. Furthermore, such terms may be used to indicate a material is not less than 50%, not less than 95%, or not less than 99% of a multi-component (i.e., two or more component system). Unless otherwise indicated, such material percentages are based on atomic percentage. As used herein, the terms “monolithic”, “monolithically integrated”, and similar terms indicate the components of the monolithic overall structure form an indivisible whole not reasonably capable of being separated.

Apparatuses, systems, device structures, and techniques are described herein related to capacitor insulator material stacks deploying layers of hafnium oxide or zirconium oxide interleaved with alumina. The resultant superlattice material is resilient to high temperature, high pressure, and long duration hydrogen or deuterium anneals for underlying transistors.

As discussed, metal-insulator-metal (MIM) capacitors may be formed over a device layer including field effect transistors (FETs) such that the capacitors are within or immediately adjacent the interconnect stack that is over the device layer. The FETs may be FinFETs, planar FETs, gate-all-around FETs (GAA-FETs), or any other suitable transistor architecture. Furthermore, the MIM capacitors may be planar capacitors, deep hole or deep trench capacitors, or any other capacitor architecture. Notably, it may be desirable to deploy a high temperature, high pressure, and long duration hydrogen and/or deuterium anneal to improve the performance of the transistors of the device layer. The hydrogen and/or deuterium anneal may passivate dangling bonds in the transistor gate oxide, for example. The discussed anneal diffuses hydrogen and/or deuterium through the interconnect stack, including the MIM capacitors.

In some embodiments, the MIM capacitor includes an insulator material between first and second electrodes. The insulator material has interleaved first and second materials. In some embodiments, the first material is hafnium oxide or zirconium oxide, and the second material is alumina, with the stack being formed such that the overall insulator material has a relatively low aluminum concentration such as an aluminum concentration in the range of one to three atomic percent. In prior material systems, the insulator material of the MIM capacitors is degraded by the discussed hydrogen and/or deuterium anneal, causing reliability problems in terms of voltage acceleration factor (VAF) and maximum supportable voltage (Vmax), for example. The materials discussed herein maintain reliability of the MIM capacitors after such anneal processing. In addition, the discussed materials may have improved VAF and/or Vmax relative to prior material systems in some contexts even after anneal processing. These and other advantages will be evident based on the following disclosure.

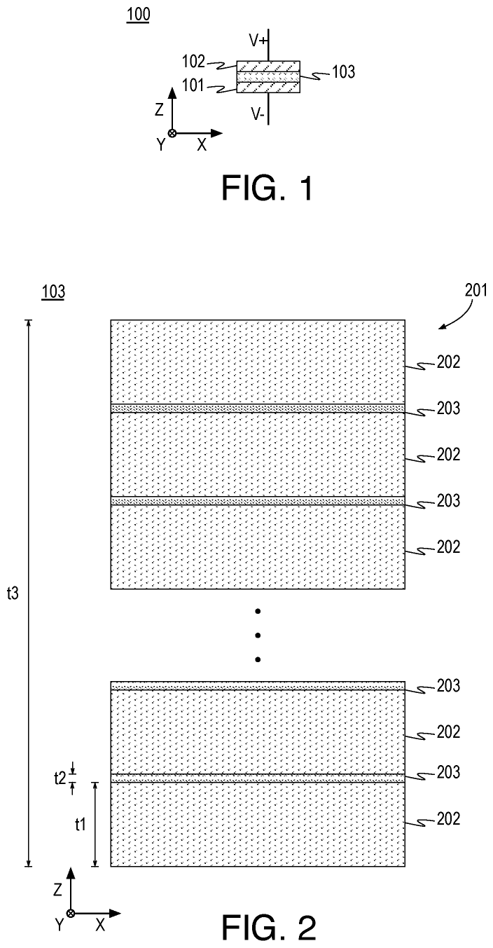

FIG. 1 illustrates a schematic of an example capacitor 100, arranged in accordance with at least some implementations of the present disclosure. As shown in FIG. 1, capacitor 100 includes a multi-layer material stack 103 between electrodes 101, 102. As discussed in detail herein, multi-layer material stack 103 is a superlattice or multilayer stack including interleaved first and second materials. The first material is hafnium oxide or zirconium oxide (e.g., a material including oxygen and one of hafnium or zirconium) and the second material includes aluminum. For example, the second material may be alumina (e.g., aluminum oxide). The materials, thicknesses, interleaving, and so on, of multi-layer material stack 103 are engineered to be resilient to high temperature (i.e., 350° C. or higher), high pressure (i.e., 300 psi or more), and long duration (i.e., one hour or longer) anneal processing. For example, the anneal processing may be hydrogen and/or deuterium anneal processing to passivate dangling bonds of a gate oxide (e.g., silicon oxide) of underlying transistors.

Electrodes 101, 102 may be on multi-layer material stack 103, or an intervening layer may be between one or both electrodes 101, 102 and multi-layer material stack 103. In some embodiments, a hafnium oxide or zirconium oxide material layer of multi-layer material stack 103 is directly on each of electrodes 101, 102. In some embodiments, electrode 101 is or includes a titanium nitride layer on which multi-layer material stack 103 may be formed. However, electrode 101 and electrode 102 may be any suitable material such as tantalum nitride, niobium nitride, ruthenium, tungsten, molybdenum, or combinations of such materials. The multi-layer nature of multi-layer material stack 103 is not illustrated in FIG. 1 for the sake of clarity of presentation. Although illustrated with respect to deployment in capacitor 100, which has a planar MIM capacitor structure, multi-layer material stack 103 may be deployed in any suitable capacitor architecture or any other suitable device context.

FIG. 2 illustrates a cross-sectional side view of an example multi-layer material stack 103 for use in a capacitor, arranged in accordance with at least some implementations of the present disclosure. As shown in FIG. 2, multi-layer material stack 103 includes a number of interleaved first materials 202 and second materials 203. Multi-layer material stack 103 may be characterized as a superlattice 201 or superlattice layer as it is periodic, and first materials 202 and second materials 203 have thicknesses t1 and t2, respectively, on the order of nanometers. First materials 202 and second materials 203 may be characterized as material layers, layers, films, or the like.

First materials 202 may be any suitable material for the bulk portion of superlattice 201. In some embodiments, first materials 202 are each hafnium oxide (e.g., first materials 202 each include hafnium and oxygen). In some embodiments, first materials 202 are each amorphous hafnium oxide. As used herein, the term amorphous indicates a solid material lacking long-range order. In some embodiments, first materials 202 are each amorphous hafnium dioxide (e.g., HfO₂) such that each of first materials 202 are one-third hafnium and two-thirds oxygen. However, other stoichiometries may be used. In some embodiments, first materials 202 are each pure hafnium oxide such that the sum of hafnium and oxygen in first materials 202 is not less than 99%.

In some embodiments, first materials 202 are each zirconium oxide (e.g., first materials 202 each include zirconium and oxygen). As discussed with respect to hafnium oxide, in some embodiments, first materials 202 are each amorphous. In some embodiments, first materials 202 are each amorphous hafnium dioxide (e.g., ZrO₂) such that each of first materials 202 are one-third hafnium and two-thirds oxygen, although other stoichiometries may be deployed. In some embodiments, first materials 202 are each pure zirconium oxide such that the sum of hafnium and oxygen in first materials 202 is not less than 99%.

As discussed, in some embodiments each of first materials 202 are hafnium oxide or zirconium oxide. Intervening and interleaved second materials 203 include aluminum. In some embodiments, intervening and interleaved second materials 203 include aluminum such that the concentration of aluminum in superlattice 201 (e.g., the entirety of multi-layer material stack 103) is in the range of one to three percent. For example, the thicknesses and characteristics of first materials 202 second materials 203 may be engineered such that the concentration of aluminum in superlattice 201 is in the range of one to three percent. In some embodiments, second materials 203 are each alumina or aluminum oxide (e.g., second materials 203 each include aluminum and oxygen). In some embodiments, second materials 203 are each amorphous. For example, superlattice 201 may be an amorphous multi-layer material stack 103.

Any number of first materials 202 and interleaved second materials 203 may be included in superlattice 201 at any suitable thicknesses t1 and t2, respectively, to form multi-layer material stack 103 having an overall thickness t3. Although illustrated with respect to thicknesses t1 being the same for each instance of first materials 202, the thicknesses may be varied vertically across multi-layer material stack 103 For example, thicknesses t1 may increase monotonically in the positive z-direction (and between first and second electrodes, which are illustrated herein below) such that each layer has the same or increasing thickness moving through multi-layer material stack 103 in the positive z-direction. Similarly, although illustrated with respect to thicknesses t2 being the same for each instance of second materials 203, the thicknesses t2 may vary in the positive z-direction of multi-layer material stack 103.

In some embodiments, thickness t1 of any instance of first material 202 is in the range of 2 to 15 angstroms. In some embodiments, thickness t1 of any instance of first material 202 is in the range of 8 to 12 angstroms. In some embodiments, thickness t1 of any instance of first material 202 is in the range of 2 to 9 angstroms. In some embodiments, thickness t1 of any instance of first material 202 is not more than 15 angstroms. In some embodiments, thickness t1 of any instance of first material 202 is not more than 12 angstroms. In some embodiments, thickness t1 of any instance of first material 202 is not more than 9 angstroms. Other thicknesses may be used. In some embodiments, thickness t2 of any instance of second material 203 is in the range of 1 to 3 angstroms.

Any number of instances of first material 202 and second material 203 may be used in superlattice 201. As shown, in some embodiments, both the top and bottom materials or material layers of superlattice 201 are first material 202. In such embodiments, superlattice 201 includes an odd number (N) of first materials 202 and one less the number (N−1) layers of second materials 203. However, in other embodiments, the bottom and top materials may be different, with first materials 202 and second materials 203 having the same number of instances in superlattice 201. And, in some embodiments, second materials 203 may be on the top and bottom of superlattice 201 and the discussed relationship may be reversed. In some embodiments, superlattice 201 includes two to fifteen (N) instances of first materials 202. In the context of fifteen instances of first materials 202, fourteen (N−1), fifteen (N), or sixteen (N+1) instances of second materials 202 are deployed depending on whether the top and bottom are both first materials 202, one of the top and bottom are first material 202 and the other is second material 203, or the top and bottom are both second materials 203, respectively. Although two to fifteen instances of first materials 202 may be deployed in some contexts, additional layers of first materials 202 may be used in some applications. In some embodiments, superlattice 201 includes at least four instances of first materials 202. In some embodiments, superlattice 201 includes at least eight instances of first materials 202. In some embodiments, superlattice 201 includes at least twelve instances of first materials 202.

The deployment of such thicknesses and number of instances of first materials 202 and second materials 203 provides an overall thickness t3 of multi-layer material stack 103. In some embodiments, thickness t3 of multi-layer material stack 103 is in the range of 40 to 120 angstroms. In some embodiments, thickness t3 of multi-layer material stack 103 is not more than 100 angstroms. In some embodiments, thickness t3 of multi-layer material stack 103 is not more than 80 angstroms. In some embodiments, thickness t3 of multi-layer material stack 103 is not more than 60 angstroms. In addition, the thicknesses and number of instances of first materials 202 and second materials 203, as well as the stoichiometries of first materials 202 and second materials 203 are selected to provide a desired composition of multi-layer material stack 103, such that multi-layer material stack 103 may be resilient to anneal processing as discussed herein.

In some embodiments, the overall composition of multi-layer material stack 103 (e.g., across thickness t3 in the z-dimension and across an exemplary area in the x-y plane) may provide an aluminum concentration of one to three percent. The overall composition of multi-layer material stack 103 may also be evident in a pertinent sub-volume of multi-layer material stack 103 since superlattice 201 is periodic in nature. For example, a sample volume of multi-layer material stack 103 may have the same or similar characteristics as those of the entirety of multi-layer material stack 103.

As discussed, multi-layer material stack 103 may have a concentration of aluminum in the range of one to three percent. In some embodiments, multi-layer material stack 103 has a concentration of aluminum of not more than three percent. In some embodiments, multi-layer material stack 103 has a concentration of aluminum of not more than two percent. In some embodiments, multi-layer material stack 103 has a concentration of aluminum of not more than 1.5 percent. In some embodiments, multi-layer material stack 103 has a concentration of aluminum in the range of one to two percent.

In some embodiments, multi-layer material stack 103 has a concentration of aluminum in the range of one to three percent or any other range discussed above, and the balance of multi-layer material stack 103 is oxygen and hafnium or zirconium to a particular level of purity such as multi-layer material stack 103 being 99% oxygen, aluminum, and one of hafnium or zirconium, or multi-layer material stack 103 being 99.9% oxygen, aluminum, and one of hafnium or zirconium.

In some embodiments, first materials 202 of multi-layer material stack 103 are hafnium dioxide (HfO₂) or zirconium dioxide (ZrO₂). For example, multi-layer material stack 103 may have a concentration of aluminum in the range of one to three percent, not less than thirty percent oxygen, and not less than sixty percent hafnium or not less than sixty percent zirconium. In some embodiments, multi-layer material stack 103 has a concentration of aluminum of not more than three percent, not less than 31 percent oxygen, and not less than 64 percent hafnium or not less than sixty percent zirconium. In some embodiments, multi-layer material stack 103 has a concentration of aluminum of not more than two percent, not less than 31 percent oxygen, and not less than 64 percent hafnium or not less than sixty percent zirconium. In some embodiments, multi-layer material stack 103 has a concentration of aluminum of not more than 1.5 percent, not less than 32 percent oxygen, and not less than 65 percent hafnium or not less than sixty percent zirconium.

Multi-layer material stack 103, having any characteristics discussed herein, may be deployed in any suitable capacitor structure or architecture such as those illustrated herein. Furthermore, the capacitor including multi-layer material stack 103 may be used in any suitable integrated circuit context. In some embodiments, a capacitor includes first and second metal electrodes, and multi-layer material stack 103 between the first and second electrodes. The capacitor may be in a metallization layer of an integrated circuit (IC) die such that the metallization layer includes one or more metal and via layers over a device layer. The device layer may include a transistor that is coupled to the capacitor, and the transistor may have an oxide gate dielectric. As discussed, the performance of the transistor may be improved by hydrogen and/or deuterium anneal processing and multi-layer material stack 103 is resilient to such processing. In some embodiments, multi-layer material stack 103 maintains its advantageous electrical properties even after trapped hydrogen and/or deuterium in multi-layer material stack 103 due to the hydrogen and/or deuterium anneal processing. The resultant IC die, including the transistor and capacitor may thereby provide improved performance of both devices. In some embodiments, the transistor is a FinFET and the capacitor is a deep trench or deep hole MIM. However, other architectures may be used.

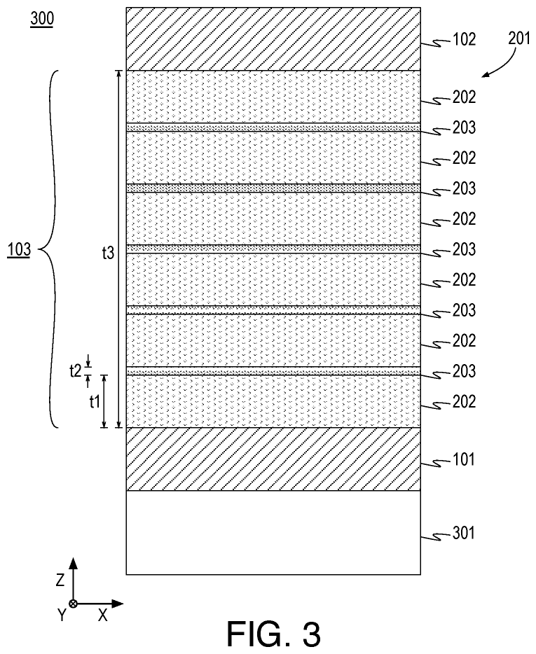

FIG. 3 illustrates a cross-sectional side view of an example capacitor device structure 300 having an anneal resilient insulator layer, arranged in accordance with at least some implementations of the present disclosure. As shown in FIG. 3, capacitor device structure 300 includes a substrate 301, bottom electrode 101, multi-layer material stack 103, and top electrode 102. Bottom electrode 101, multi-layer material stack 103, and top electrode 102 may be formed using any suitable technique or techniques such as those discussed herein below.

In some embodiments, substrate 301 is a material used to manufacture integrated circuits inclusive of semiconductor materials such as, but not limited to, single crystal silicon, polycrystalline silicon and silicon on insulator (SOI). In some embodiments, substrate 301 includes other semiconductor materials such as germanium, silicon germanium, or a suitable group III-V or group III-N compound. Substrate 301 may also include semiconductor materials, metals, dopants, and other materials commonly found in semiconductor substrates. In some embodiments, substrate 301 includes a device layer (e.g., FET transistor devices), metallization stack(s), or other device layers. As discussed, in some embodiments, after fabrication of the device layer and metallization layers or levels including MIM capacitor structures, the resultant workpiece is annealed to passivate dangling bonds in the transistor gate oxide (i.e., in the device layer), with multi-layer material stack 103 being resilient to the anneal processing.

Bottom electrode 101 may include any suitable conductive material such as a metal. In some embodiments, bottom electrode 101 is or includes a layer of titanium nitride (TiN, e.g., titanium and nitrogen). In some embodiments, bottom electrode 101 is or includes tungsten (W), tantalum nitride (TaN, e.g., tantalum and nitrogen), niobium nitride (NbN, e.g., niobium and nitrogen), ruthenium (Ru), ruthenium oxide (RuOx) iridium (Ir), aluminum (Al), palladium (Pd), tin (Sn), copper (Cu), titanium (Ti), cobalt (Co), chromium (Cr), molybdenum (Mo), molybdenum nitride (MoN), lanthanum (La), nickel (Ni), gold (Au), platinum (Pt), scandium (Sc), or combinations of these materials.

As shown, in some embodiments, capacitor device structure 300 includes one of first materials 202 directly on electrode 101, and another of first materials 202 directly on electrode 102. Such an architecture may provide for a more robust multi-layer material stack 103.

However, one or both of electrodes 101, 102 may be on second materials 203 in some implementations. In any event, multi-layer material stack 103 is between electrode 101 and electrode 102.

As discussed, multi-layer material stack 103 is an electrical insulator material and is suitable for deployment in a metal-insulator-metal (MIM) capacitor. As used herein the term insulator or insulator material indicates an electrical insulator having a relatively high dielectric constant, such as a dielectric constant greater than 10. In some embodiments, multi-layer material stack 103 a dielectric constant of not less than 15 or not less than 20. As discussed, multi-layer material stack 103 includes interleaved first materials 202 and second materials 203 such that first materials 202 include oxygen and one of hafnium and zirconium, and second materials 203 include aluminum. In some embodiments, first materials 202 interleaved second materials 203 include aluminum such that the concentration of aluminum in superlattice 201 is in the range of one to three percent, with a balance of oxygen and one of hafnium and zirconium, as discussed above with respect to FIG. 2.

As shown, top electrode 102 may be on or over multi-layer material stack 103. Top electrode 102 may include any suitable conductive material such as a metal. In some embodiments, top electrode 102 is or includes a layer of titanium nitride (TiN, e.g., titanium and nitrogen). In some embodiments, top electrode 102 is or includes tungsten (W), tantalum nitride (TaN, e.g., tantalum and nitrogen), niobium nitride (NbN, e.g., niobium and nitrogen), ruthenium (Ru), iridium (Ir), aluminum (Al), copper (Cu), titanium (Ti), cobalt (Co), chromium (Cr), molybdenum (Mo), nickel (Ni), gold (Au), platinum (Pt), or combinations of these materials. In some embodiments, bottom electrode and/or top electrode 102 is or includes titanium and nitrogen, tantalum and nitrogen, niobium and nitrogen, ruthenium, tungsten, or molybdenum.

Although illustrated in FIG. 3 as a part of a planar capacitor structure, multi-layer material stack 103 may be deployed in any capacitor structure.

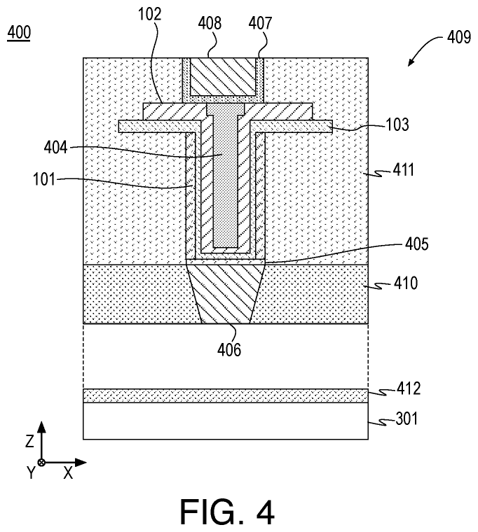

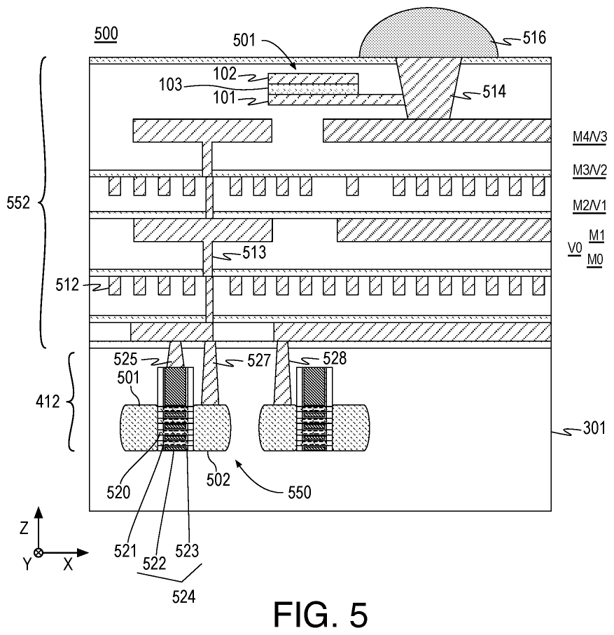

FIG. 4 illustrates a cross-sectional side view of an exemplary deep trench capacitor 400 having an anneal resilient insulator layer, arranged in accordance with some embodiments of the disclosure. As shown, deep trench capacitor 400 and/or other components discussed herein may be deployed as part of an IC die 409, which is coupled to other components such as a power supply as is known in the art and as illustrated and discussed with respect to FIG. 8. In the example of FIG. 4, deep trench capacitor 400 may be deployed over a device layer and within a metallization layer or layers as illustrated with respect to the MIM capacitor of FIG. 5 herein below. Deep trench capacitor 400 may have any cross-sectional shape in the x-y plane such as a circular, ovular, or an extended trench shape.

In some embodiments, deep trench capacitor 400 may be characterized as a deep hole capacitor. Such deep trench and deep hole capacitor architectures advantageously have a large capacitive surface area relative to the x-y planar area taken up by the capacitor. Deep trench capacitor 400 may have a U-shape (as shown) or a V-shape, as taken in cross-section in the x-z plane. As shown, deep trench capacitor 400 includes electrode 101, electrode 102, multi-layer material stack 103 (illustrated as a single component for the sake of clarity), a metal via 404, a barrier layer 405, an interconnect 406, a barrier layer 407, and an interconnect 408. Electrode 101 is coupled to interconnect 406 via barrier layer 405 and electrode 102 is coupled to interconnect 408 via metal via 404 and barrier layer 407. Deep trench capacitor 400 is formed in insulator 411 (e.g., silicon oxide, SiO₂), interconnect 406 is embedded in insulator 410, which may the same or different material as insulator 411, and such components are formed over substrate 301. Notably, substrate 301 may include a device layer 412. As discussed, device layer 412 may include transistors having an oxide gate dielectric that is treated using hydrogen and/or deuterium anneal processing as discussed herein.

FIG. 5 illustrates a cross-sectional side view of an integrated circuit (IC) device structure 500 including transistor structures 550 in a device layer 412, and a metal-insulator-metal (MIM) capacitor 501 within metallization layers 552 over device layer 412, arranged in accordance with some embodiments of the disclosure. Although illustrated as a planar MIM capacitor 501, in accordance with capacitor 100, any capacitor structure discussed herein may be deployed in IC device structure 500. Furthermore, planar MIM capacitor 501 may be formed in any position within metallization layers 552 such as a single metal or via level of metallization layers 552. In some embodiments, planar MIM capacitor 501 may be formed over metallization layers 552. Furthermore, although illustrated with planar MIM capacitor 501 and GAA-FET transistor structure 550, any capacitor and FET architectures or structures may be implemented in IC device structure 500. In some embodiments, as shown, planar MIM capacitor 501 is coupled, via electrode 101 to a via 514 of metallization layers 552, with via 514 in contact with a device level interconnect 516 (e.g., a bump or other interconnect structure).

Metallization layers 552 may be formed using any suitable technique or techniques such as dual damascene techniques, single damascene techniques, subtractive metallization patterning techniques, or the like. For example, interconnectivity, signal routing, power-delivery, and the like may be provided by metallization layers 552. As used herein, the term metallization layer indicates metal interconnections or wires that provide electrical routing. Adjacent metallization layers, such as metallization interconnects 512, are interconnected by vias, such as vias 513, that may be characterized as part of the metallization layers. As shown, in some embodiments, metallization layers 552 are formed over and immediately adjacent transistor structure 550. In the illustrated example, metallization layers 552 include M0, V0, M1, M2/V1, M3/V2, and M4/V3. However, metallization layers 552 may include any number of metallization layers such as six, eight, or more metallization layers.

Transistor structures 550 may have been fabricated prior to metallization layers 552 and planar MIM capacitor 501. Transistor structures 550 include source structures 501, drain structures 502, channel regions 521 of semiconductor structures 520, gate structures 524 that include gate electrode 522 and gate dielectric 523, drain contact 527, gate contact 525, and source contact 528. Subsequent to fabrication of metallization layers 552 and deep trench capacitor 400, gate dielectric 523 of transistor structures 550 is hydrogen and/or deuterium anneal treated as discussed herein below.

Semiconductor structures 520 may be any suitable semiconductor material such as silicon, germanium, silicon germanium, a III-V material, a TMD material, or others. Although illustrated with respect to GAA-FETs, transistor structures 550 may be FinFETs, planar-FETs, or any other transistor architecture. Source structures 501 and drain structures 502 may be grown epitaxially from exposed semiconductor structures 520, and source structures 501 and drain structures 502 may include any suitable material or materials for the conductivity type of the transistor structure being formed. For n-type metal oxide semiconductor (NMOS) transistors, source structure 501 and drain structure 502 may be epitaxial silicon doped with n-type dopants inclusive of phosphorous, arsenic, antimony, or others. For p-type metal oxide semiconductor (PMOS) GAA transistors, source structure 501 and drain structure 502 may be epitaxial silicon germanium doped with p-type dopants inclusive of boron, aluminum, gallium, indium, or others.

Gate structures 524 include gate dielectric 523 separating gate electrodes 522 from channel regions 521 of semiconductor structures 520. Gate dielectric 523 may be silicon oxide, aluminum oxide, or a high-k dielectric, such as hafnium oxide. Gate electrodes 522 may include any suitable work function metal for gate control such as tantalum, titanium, aluminum, ruthenium, or alloys of such materials. Drain contact 527, source contact 528, and gate contact 525 may include any suitable conductive contact materials such as tungsten, copper, cobalt, aluminum, titanium, or the like.

As shown, metallization layers 552 are over device layer 412. In some embodiments, planar MIM capacitor 501 is vertically over transistor structure 550 such that one or more components of planar MIM capacitor 501 are vertically aligned with one or more components of transistor structure 550.

Discussion now turns to fabrication processes for forming a capacitor having an anneal resilient insulator layer, and hydrogen and/or deuterium annealing, for example, gate dielectric 523 of transistor structure 550. In some embodiments, hydrogen and/or deuterium are used to passivate dangling bonds at the interface of gate dielectric 523 (e.g., a silicon-oxide interface). Such processing may include high temperatures (e.g., 350° C. or higher), high pressures (e.g., 300 psi or more), and extended duration (e.g., an hour or longer) anneal processing that necessitates the diffusion of hydrogen and/or deuterium through metallization layers 552 (e.g., the interconnect stack), including deep trench capacitor 400 (e.g., MIM capacitors). As discussed, multi-layer material stack 103 makes deep trench capacitor 400 advantageously resilient to this diffusion processing.

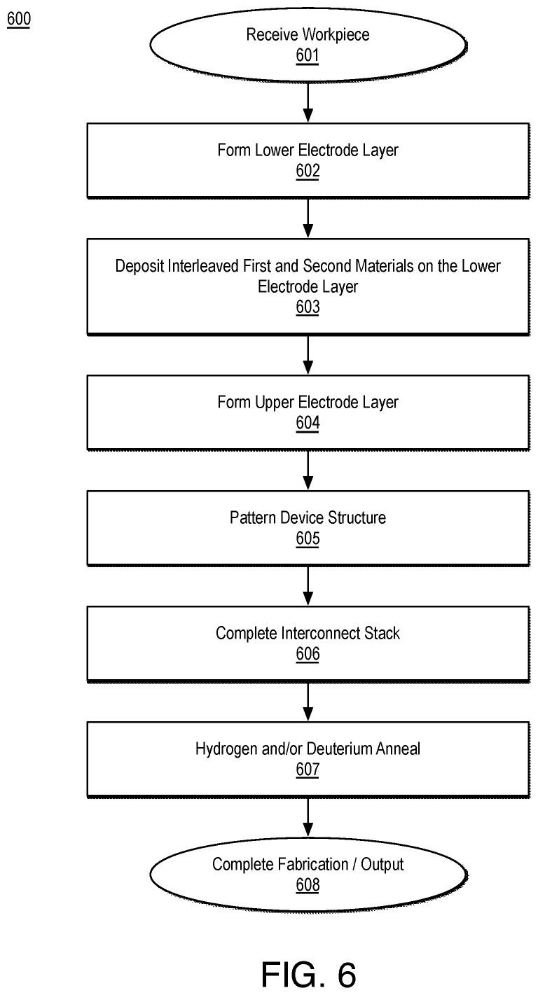

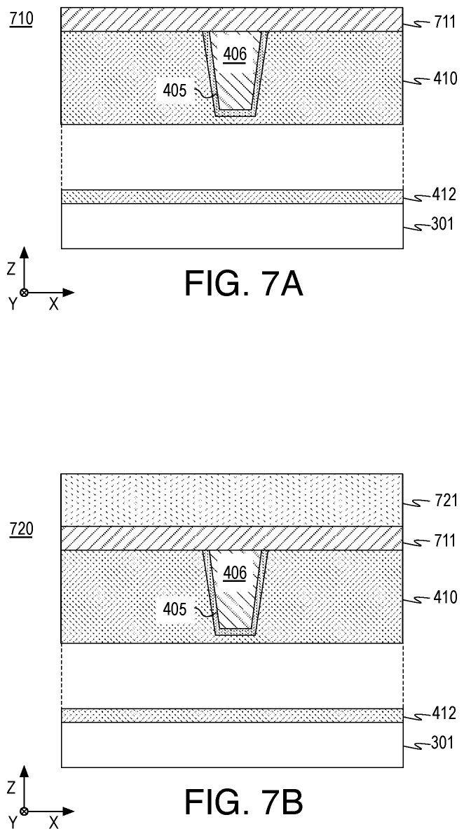

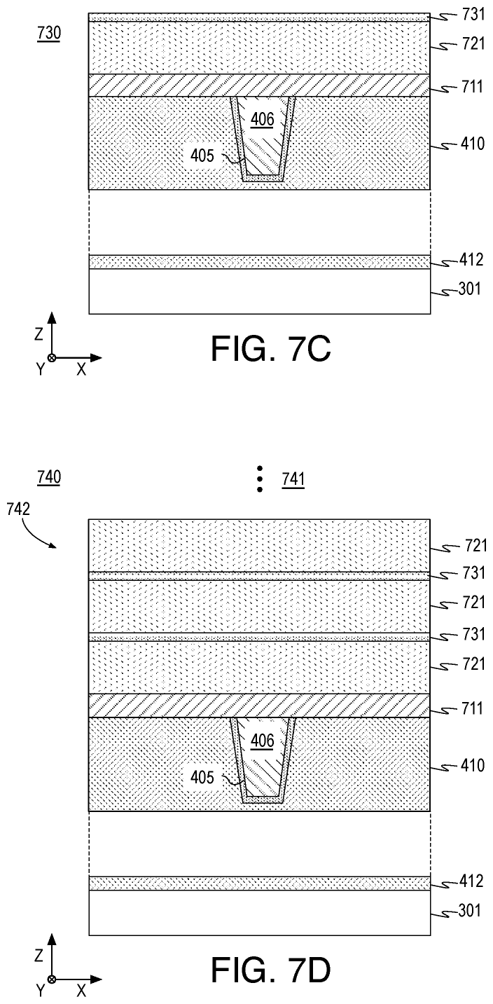

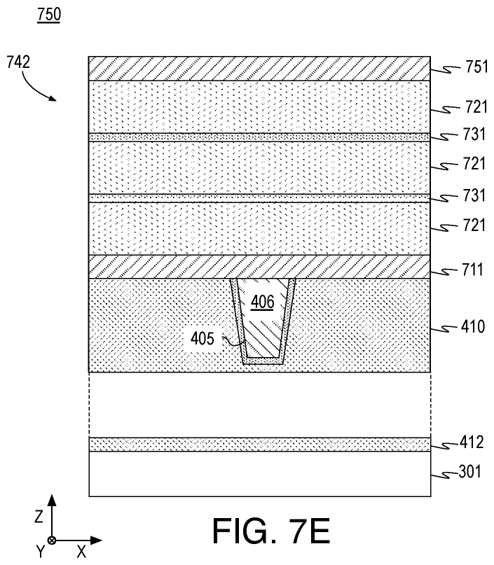

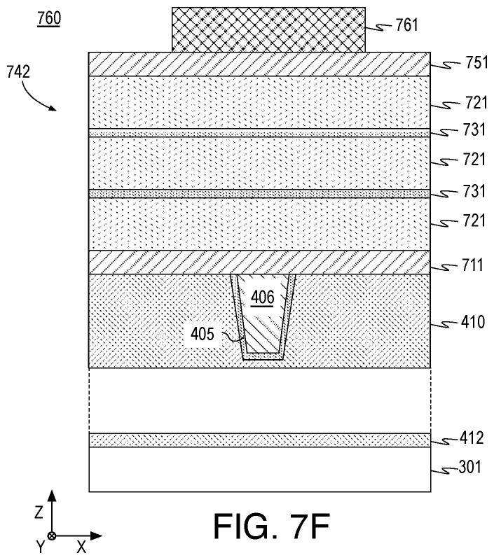

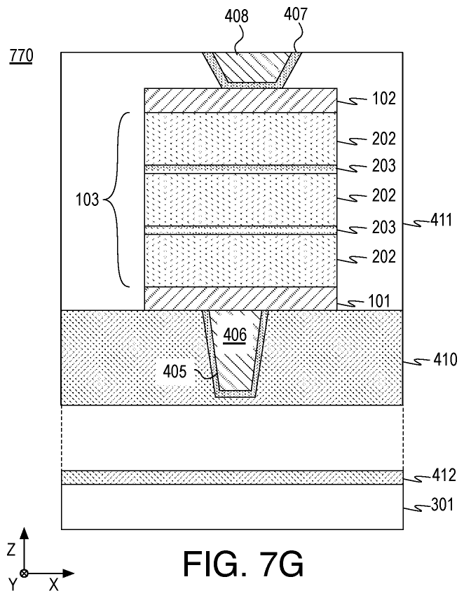

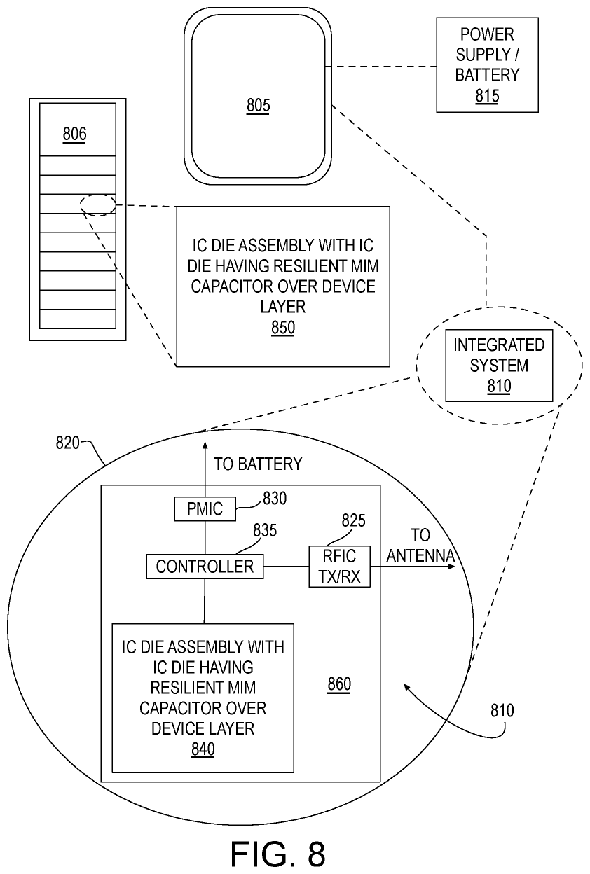

FIG. 6 is a flow diagram illustrating methods 600 for forming a capacitor device structure having an anneal resilient insulator layer and annealing an underlying field effect transistor, arranged in accordance with some embodiments of the disclosure. Methods 600 may be practiced, for example, to fabricate any of capacitor devices discussed herein. Although illustrated with respect to fabricating a planar capacitor, methods 600 may be used to fabricate any capacitor or suitable device that includes an anneal resilient insulator layer. FIGS. 7A, 7B, 7C, 7D, 7E, 7F, and 7G are cross-sectional views of a device structure evolving as methods 600 are practiced, arranged in accordance with some embodiments of the disclosure.

Methods 600 begin at input operation 601 where a workpiece including one or more material layers of a monolithic IC is received. In some embodiments, the workpiece is a large format (e.g., 300-450 mm) wafer and includes at least a device coupling or metallization layer on a working surface of the wafer. In some embodiments, the received workpiece has a device layer including field effect transistors and one or more overlying metallization layers, as illustrated and discussed with respect to FIG. 5.

Processing continues at operation 602, where a lower electrode layer is formed using any suitable technique or techniques such as blanket deposition techniques including atomic layer deposition (ALD) processing. In the example illustrated in FIG. 7A, device structure 710 includes an interconnect 406 over substrate 301 and over device layer 412, with interconnect 406 on a barrier layer 405. Interconnect 406 and barrier layer 405 are embedded within insulator 410. Insulator 410 may be silicon dioxide, silicon nitride, silicon carbide, or a low-k dielectric such as carbon doped silicon oxide. Barrier layer 405 may include tantalum, tantalum nitride, or ruthenium, for example. Interconnect 406 includes a fill metal that may be cobalt, copper, tungsten, or ruthenium, for example.

As shown in FIG. 7A, device structure 710 also includes a lower electrode material layer 711 (as formed at operation 602), which is to become electrode 101 of device structure 770. Electrode material layer 711 may include any material or materials as discussed herein with respect to electrodes 101, 102. In some embodiments, electrode material layer 711 is titanium nitride (e.g., includes titanium and nitrogen). However, other materials discussed herein may be used. Electrode material layer 711 may be formed using any suitable technique or techniques such as blanket deposition. The blanket deposition may be performed with an ALD process, for example.

Returning to FIG. 6, methods 600 continue at operation 603, where a multi-layer capacitor material stack is blanket deposited adjacent the lower electrode material layer. The multi-layer capacitor material stack includes an interleaved stack of first and second materials as discussed above such that the first material is hafnium oxide or zirconium oxide and the interleaved material includes aluminum. For example, material layers corresponding to the components of any multi-layer material stack 103 discussed herein may be blanket deposited at operation 603. Any deposition technique or techniques known to be suitable for deposition of the materials of a multi-layer capacitor material stack may be performed at operation 603, but in some exemplary embodiments, one or more layers of the multi-layer capacitor material stack are deposited with an ALD process. In some embodiments, operation 603 includes forming a superlattice material layer adjacent the first electrode material by iteratively depositing first and second materials of the superlattice material layer, the first material comprising oxygen and one of hafnium and zirconium, and the second material comprising aluminum.

In some embodiments, multiple adjacent layers of the multi-layer capacitor material stack (and/or the layers of the lower and upper electrode) are formed while the workpiece is in the same process chamber and without breaking vacuum of the process chamber. In some embodiments, forming the first materials and second materials of the multi-layer capacitor material stack includes an iterative cycle of atomic layer deposition of hafnium oxide or zirconium oxide, followed by atomic layer deposition of alumina, followed by atomic layer deposition of hafnium oxide or zirconium oxide, followed by atomic layer deposition of alumina, and so on, all within a continuously sealed process chamber.

FIG. 7B illustrates an example device structure 720 similar to device structure 710 after blanket deposition of a first material layer 721. First material layer 721 may include any material or materials as discussed herein with respect to first materials 202. In some embodiments, first material layer 721 is hafnium oxide or zirconium oxide. In some embodiments, first material layer 721 is amorphous hafnium oxide or amorphous zirconium oxide. In some embodiments, first material layer 721 is hafnium dioxide or zirconium dioxide. First material layer 721 may be formed using any suitable technique or techniques such as an ALD process, for example. As shown, in some embodiments, first material layer 721 is formed directly on lower electrode material layer 711.

FIG. 7C illustrates an example device structure 730 similar to device structure 720 after blanket deposition of a second material layer 731. Second material layer 731 may include any material or materials as discussed herein with respect to second materials 203. In some embodiments, second material layer 731 includes aluminum. In some embodiments, second material layer 731 is alumina. In some embodiments, second material layer 731 is amorphous alumina. Second material layer 731 may be formed using any suitable technique or techniques such as an ALD process, for example. In some embodiments, first material layer 721 and second material layer 731 are formed by ALD processing in the same process chamber and without breaking the vacuum of the chamber during deposition of first material layer 721 and second material layer 731.

FIG. 7D illustrates an example device structure 740 similar to device structure 730 after continued blanket deposition of first material layers 721 and interleaved second material layers 731. First material layers 721 and second material layers 731 may include any material or materials as discussed herein with respect to first materials 202 and second materials 203, and the resulting multi-layer material stack 742 as formed by continued processing 741 may have any characteristics discussed with respect to multi-layer material stack 103. In some embodiments, first material layers 721 and second material layers 731 are formed by ALD processing in the same process chamber and without breaking the vacuum of the chamber during continued processing 741.

Returning to FIG. 6, processing continues at operation 604, where an upper electrode material layer is blanket deposited on the multi-layer capacitor material stack deposited at operation 603. Although any deposition technique or techniques known to be suitable for such deposition may be practiced at operation 604, in some exemplary embodiments, the upper electrode material layer is deposited with an ALD process.

FIG. 7E illustrates an example device structure 750 similar to device structure 740 after blanket deposition of an electrode material layer 751 on multi-layer material stack 742. Upper electrode material layer 751 is to become electrode 102 of device structure 770. Electrode material layer 751 may include any material or materials as discussed herein with respect to electrodes 101, 102. In some embodiments, electrode material layer 751 is titanium nitride (e.g., includes titanium and nitrogen). However, any materials discussed herein may be used. Electrode material layer 751 may be formed using any suitable technique or techniques such as an ALD process, for example. Although illustrated with respect to three first material layers 721 and two second material layers 731, multi-layer material stack 742 may include any number of first material layers 721 and second material layers 731, as discussed herein with respect to multi-layer material stack 103.

Returning to FIG. 6, methods 600 continue at operation 605, where the device material layers formed at operations 602-604 are patterned with any subtractive process(es) suitable for the various material layer compositions. In some embodiments, a mask such as a lithographic mask is formed over the device material layers and the device material layers are patterned using etch techniques.

FIG. 7F illustrates an example device structure 760 similar to device structure 750 after patterning a mask 761 on or over multi-layer material stack 742. Mask 761 defines a polygon area and position of a device for patterning multi-layer material stack 742, for example, relative to interconnect 406. Mask 761 may be formed with any lithographic process(es).

FIG. 7G illustrates an example device structure 770 similar to device structure 760 after the patterning of multi-layer material stack 742. In some embodiments, multi-layer material stack 742 may be patterned with one or more plasma etch processes. Such etch processing defines sidewalls into the various material layers 711, 721, 731, 751 to form electrode 101, multi-layer material stack 103, and electrode 102, respectively. FIG. 7G further illustrates an example where an upper-level interconnect 408 and barrier layer 407 has been fabricated in contact with electrode 102, with upper-level interconnect 408, barrier layer 407, electrode 101, multi-layer material stack 103, and electrode 102 embedded in insulator 411. Barrier layer 407 may provide for improved adhesion and may include, for example, tantalum, tantalum nitride, or ruthenium in contact with electrode 102. Interconnect 408 may include any suitable fill metal such as cobalt, tungsten, or copper.

Returning to FIG. 6, methods 600 continue at operation 606, where, following device patterning, any remaining interconnect levels of the IC die may be completed, as illustrated with respect to FIG. 5, for example. Processing continues at operation 607, where a hydrogen and/or deuterium anneal may be performed. With reference to FIG. 5, in some embodiments, hydrogen and/or deuterium are used to passivate dangling bonds at an interface of gate dielectric 523. Such processing necessitates the diffusion of hydrogen and/or deuterium through metallization layers 552 (e.g., the interconnect stack), including a capacitor such as the capacitor of device structure 770 or any other capacitor discussed herein. Notably, the interleaved multi-layer material stack formed at operation 603 makes the fabricated deep trench capacitor resilient to this diffusion processing. the hydrogen and/or deuterium anneal processing of operation 607 may be performed using any suitable technique or techniques. In some embodiments, the hydrogen and/or deuterium anneal processing is a high temperature (e.g., 350° C. or higher), high pressures (e.g., 300 psi or more), and extended duration (e.g., an hour or longer) anneal process operation.

As shown at operation 608, fabrication may be completed and the resultant structure may be output. Such processing may include any additional backend processing, dicing, packaging, assembly, and so on. The resultant device (e.g., integrated circuit die) may then be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like. Although illustrated with respect to device structure 770 being a thin film capacitor, methods 600 may be extended for use to fabricate other device architectures such as deep trench capacitor 400, or others.

FIG. 8 illustrates exemplary systems employing an IC die having a capacitor device structure with an anneal resilient insulator layer and an underlying field effect transistor, in accordance with some embodiments. The system may be a mobile computing platform 805 and/or a data server machine 806, for example. Either may employ an IC die having a capacitor device structure with an anneal resilient insulator layer and an underlying field effect transistor as described herein. Server machine 806 may be any commercial server, for example including any number of high-performance computing platforms disposed within a rack and networked together for electronic data processing, which in the exemplary embodiment includes an IC die assembly 850 with an IC die having a capacitor device structure with an anneal resilient insulator layer and an underlying field effect transistor as described elsewhere herein. Mobile computing platform 805 may be any portable device configured for each of electronic data display, electronic data processing, wireless electronic data transmission, or the like. For example, mobile computing platform 805 may be any of a tablet, a smart phone, a laptop computer, etc., and may include a display screen (e.g., a capacitive, inductive, resistive, or optical touchscreen), a chip-level or package-level integrated system 810, and a battery 815. Although illustrated with respect to mobile computing platform 805, in other examples, chip-level or package-level integrated system 810 and a power supply/battery 815 may be implemented in a desktop computing platform, an automotive computing platform, an internet of things platform, or the like. As discussed below, in some examples, the disclosed systems may include a sub-system 860 such as a system on a chip (SOC) or an integrated system of multiple ICs, which is illustrated with respect to mobile computing platform 805.

Whether disposed within integrated system 810 illustrated in expanded view 820 or as a stand-alone packaged device within data server machine 806, sub-system 860 may include memory circuitry and/or processor circuitry 840 (e.g., RAM, a microprocessor, a multi-core microprocessor, graphics processor, etc.), a power management integrated circuit (PMIC) 830, a controller 835, and a radio frequency integrated circuit (RFIC) 825 (e.g., including a wideband RF transmitter and/or receiver (TX/RX)). As shown, one or more IC dice, such as memory circuitry and/or processor circuitry 840 may be assembled and implemented such that one or more include an IC die having a capacitor device structure with an anneal resilient insulator layer and an underlying field effect transistor. In some embodiments, RFIC 825 includes a digital baseband and an analog front end module further comprising a power amplifier on a transmit path and a low noise amplifier on a receive path). Functionally, PMIC 830 may perform battery power regulation, DC-to-DC conversion, etc., and so has an input coupled to power supply/battery 815, and an output providing a current supply to other functional modules. As further illustrated in FIG. 8, in the exemplary embodiment, RFIC 825 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 840 may provide memory functionality for sub-system 860, high level control, data processing and the like for sub-system 860. In alternative implementations, each of the SOC modules may be integrated onto separate ICs coupled to a package substrate, interposer, or board.

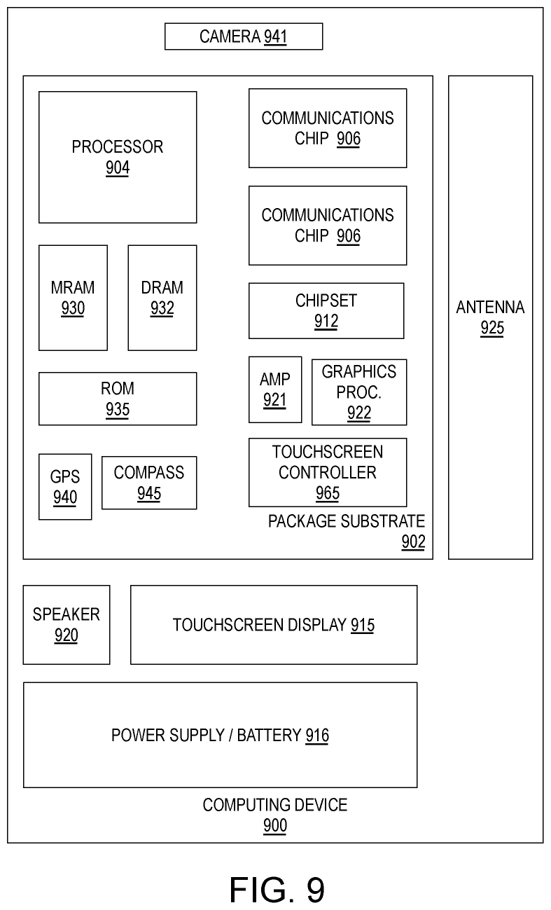

FIG. 9 is a functional block diagram of an electronic computing device 900, in accordance with some embodiments. For example, device 900 may, via any suitable component therein, deploy an IC die having a capacitor device structure with an anneal resilient insulator layer and an underlying field effect transistor in accordance with any embodiments described elsewhere herein. Device 900 further includes a motherboard or package substrate 902 hosting a number of components, such as, but not limited to, a processor 904 (e.g., an applications processor). Processor 904 may be physically and/or electrically coupled to package substrate 902. In some examples, processor 904 is within an IC assembly that includes an IC die having a capacitor device structure with an anneal resilient insulator layer and an underlying field effect transistor as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 906 may also be physically and/or electrically coupled to the package substrate 902. In further implementations, communication chips 906 may be part of processor 904. Depending on its applications, computing device 900 may include other components that may or may not be physically and electrically coupled to package substrate 902. These other components include, but are not limited to, volatile memory (e.g., DRAM 932), non-volatile memory (e.g., ROM 935), flash memory (e.g., NAND or NOR), magnetic memory (MRAM 930), a graphics processor 922, a digital signal processor, a crypto processor, a chipset 912, an antenna 925, touchscreen display 915, touchscreen controller 965, power supply/battery 916, audio codec, video codec, power amplifier 921, global positioning system (GPS) device 940, compass 945, accelerometer, gyroscope, speaker 920, camera 941, and mass storage device (such as hard disk drive, solid-state drive (SSD), compact disk (CD), digital versatile disk (DVD), and so forth, or the like.

Communication chips 906 may enable wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 906 may implement any of a number of wireless standards or protocols, including, but not limited to, those described elsewhere herein. As discussed, computing device 900 may include a plurality of communication chips 906. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertains to exemplary embodiments.

In one or more first embodiments, an apparatus comprises a first electrode and a second electrode, and a layer between the first electrode and second the electrode, the layer comprising oxygen, one of hafnium and zirconium, and between one and three percent aluminum.

In one or more second embodiments, further to the first embodiments, the layer comprises not more than 1.5 percent aluminum.

In one or more third embodiments, further to the first or second embodiments, the layer comprises interleaved first and second materials, the first material comprising oxygen and one of hafnium and zirconium, and the second material comprising aluminum and oxygen.

In one or more fourth embodiments, further to the first through third embodiments, the first material comprises amorphous hafnium dioxide or amorphous zirconium dioxide.

In one or more fifth embodiments, further to the first through fourth embodiments, at least one of first materials has a thickness in a range of 2 to 15 angstroms.

In one or more sixth embodiments, further to the first through fifth embodiments, the layer is on the first electrode and on the second electrode, and the layer has a thickness between the first electrode and the second electrode, the thickness in a range of 40 to 120 angstroms.

In one or more seventh embodiments, further to the first through sixth embodiments, the interleaved first and second materials comprise at least four first materials interleaved with at least three second materials.

In one or more eighth embodiments, further to the first through seventh embodiments, one of the first materials is on the first electrode and another of the first materials is on the second electrode.

In one or more ninth embodiments, an integrated circuit (IC) die comprises a capacitor in a metallization layer of the IC die, the capacitor comprising the first electrode, the second electrode, and the layer, and a device layer under the metallization layer, the device layer comprising a transistor coupled to the capacitor.

In one or more tenth embodiments, further to the first through ninth embodiments, the apparatus further comprises a power supply coupled to the IC die and/or the first electrode.

In one or more eleventh embodiments, a system comprises an IC die comprising any of the apparatuses of the first through eighth embodiments, the IC die further including a transistor coupled transistor coupled to the capacitor.

In one or more twelfth embodiments, an apparatus comprises a first electrode and a second electrode, and a superlattice layer of interleaved first and second materials between the first electrode and second the electrode, the first materials of the superlattice layer comprising oxygen and one of hafnium and zirconium, and the second materials of the superlattice layer comprising aluminum, wherein the superlattice layer comprises between one and three percent aluminum, not less than thirty percent oxygen, and not less than sixty percent hafnium or zirconium.

In one or more thirteenth embodiments, further to the twelfth embodiments, the superlattice layer comprises not more than 1.5 percent aluminum, not less than 32 percent oxygen, and not less than 65 percent hafnium.

In one or more fourteenth embodiments, further to the twelfth or thirteenth embodiments, at least one of first materials has a thickness in a range of 2 to 15 angstroms.

In one or more fifteenth embodiments, further to the twelfth through fourteenth embodiments, the superlattice layer is on the first electrode and on the second electrode, wherein the superlattice layer has a thickness between the first electrode and the second electrode, the thickness in a range of 40 to 120 angstroms, and wherein one of the first materials is on the first electrode and another of the first materials is on the second electrode.

In one or more sixteenth embodiments, further to the twelfth through fifteenth embodiments, an integrated circuit (IC) die comprises a capacitor in a metallization layer of the IC die, the capacitor comprising the first electrode, the second electrode, and the layer, and a device layer under the metallization layer, the device layer comprising a transistor coupled to the capacitor.

In one or more seventeenth embodiments, further to the twelfth through sixteenth embodiments, the apparatus further comprises a power supply coupled to the IC die and/or the first electrode.

In one or more eighteenth embodiments, a system comprises an IC die comprising any of the apparatuses of the twelfth through fifteenth embodiments, the IC die further including a transistor coupled transistor coupled to the capacitor.

In one or more nineteenth embodiments, a method comprises forming a superlattice material layer adjacent a first electrode by iteratively depositing first and second materials of the superlattice material layer, the first material comprising oxygen and one of hafnium and zirconium, and the second material comprising aluminum, and forming a second electrode adjacent the superlattice material layer, wherein the superlattice material layer comprises between one and three percent aluminum.

In one or more twentieth embodiments, further to the nineteenth embodiments, said depositing the first and second materials comprises atomic layer deposition.

In one or more twenty-first embodiments, further to the nineteenth or twentieth embodiments, the superlattice material layer comprises not more than 1.5 percent aluminum.

In one or more twenty-second embodiments, further to the nineteenth through twenty-first embodiments, least one of first materials has a thickness in a range of 8 to 15 angstroms, the superlattice material layer has a thickness in a range of 40 to 120 angstroms, the superlattice material layer comprises at least four first materials interleaved with at least three second materials, and one of the first materials is on the first electrode and another of the first materials is on the second electrode.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a first electrode and a second electrode; and
a layer between the first electrode and second the electrode, the layer comprising oxygen, one of hafnium and zirconium, and between one and three percent aluminum.

2. The apparatus of claim 1, wherein the layer comprises not more than 1.5 percent aluminum.

3. The apparatus of claim 1, wherein the layer comprises interleaved first and second materials, the first material comprising oxygen and one of hafnium and zirconium, and the second material comprising aluminum and oxygen.

4. The apparatus of claim 3, wherein the first material comprises amorphous hafnium dioxide or amorphous zirconium dioxide.

5. The apparatus of claim 3, wherein at least one of first materials has a thickness in a range of 2 to 15 angstroms.

6. The apparatus of claim 3, wherein the layer is on the first electrode and on the second electrode, and wherein the layer has a thickness between the first electrode and the second electrode, the thickness in a range of 40 to 120 angstroms.

7. The apparatus of claim 3, wherein the interleaved first and second materials comprise at least four first materials interleaved with at least three second materials.

8. The apparatus of claim 3, wherein one of the first materials is on the first electrode and another of the first materials is on the second electrode.

9. The apparatus of claim 1, wherein an integrated circuit (IC) die comprises:
a capacitor in a metallization layer of the IC die, the capacitor comprising the first electrode, the second electrode, and the layer; and
a device layer under the metallization layer, the device layer comprising a transistor coupled to the capacitor.

10. The apparatus of claim 9, further comprising a power supply coupled to the IC die.

11. An apparatus, comprising:
a first electrode and a second electrode; and
a superlattice layer of interleaved first and second materials between the first electrode and second the electrode, the first materials of the superlattice layer comprising oxygen and one of hafnium and zirconium, and the second materials of the superlattice layer comprising aluminum, wherein the superlattice layer comprises between one and three percent aluminum, not less than thirty percent oxygen, and not less than sixty percent hafnium or zirconium.

12. The apparatus of claim 11, wherein the superlattice layer comprises not more than 1.5 percent aluminum, not less than 32 percent oxygen, and not less than 65 percent hafnium.

13. The apparatus of claim 11, wherein at least one of first materials has a thickness in a range of 2 to 15 angstroms.

14. The apparatus of claim 11, wherein the superlattice layer is on the first electrode and on the second electrode, wherein the superlattice layer has a thickness between the first electrode and the second electrode, the thickness in a range of 40 to 120 angstroms, and wherein one of the first materials is on the first electrode and another of the first materials is on the second electrode.

15. The apparatus of claim 11, wherein an integrated circuit (IC) die comprises:
a capacitor in a metallization layer of the IC die, the capacitor comprising the first electrode, the second electrode, and the layer; and
a device layer under the metallization layer, the device layer comprising a transistor coupled to the capacitor.

16. The apparatus of claim 15, further comprising a power supply coupled to the IC die.

17. A method, comprising:
forming a superlattice material layer adjacent a first electrode by iteratively depositing first and second materials of the superlattice material layer, the first material comprising oxygen and one of hafnium and zirconium, and the second material comprising aluminum; and
forming a second electrode adjacent the superlattice material layer, wherein the superlattice material layer comprises between one and three percent aluminum.

18. The method of claim 17, wherein said depositing the first and second materials comprises atomic layer deposition.

19. The method of claim 17, wherein the superlattice material layer comprises not more than 1.5 percent aluminum.

20. The method of claim 17, wherein at least one of first materials has a thickness in a range of 8 to 15 angstroms, the superlattice material layer has a thickness in a range of 40 to 120 angstroms, the superlattice material layer comprises at least four first materials interleaved with at least three second materials, and one of the first materials is on the first electrode and another of the first materials is on the second electrode.
